(19) United States
(12) Patent Application Publication
(10) Pub. No.: US 2023/0102509 A1
(43) Pub. Date: Mar. 30, 2023

(54) SIMULATION APPARATUS AND METHOD FOR FIRE EVACUATION

(71) Applicant: University of Seoul Industry Cooperation Foundation, Seoul (KR)

(72) Inventors: Chul min JUN, Seoul (KR); Min Hyuck LEE, Seoul (KR); Hyun Woo NAM, Seoul (KR); Jae Young LEE, Anyang-si (KR)

(21) Appl. No.: 17/956,759

(22) Filed: Sep. 29, 2022

(30) Foreign Application Priority Data
Sep. 29, 2021 (KR) 10-2021-0128542

(51) Int. Cl. A62B 3/00; G06F 30/13

(52) U.S. Cl. CPC A62B 3/00; G06F 30/13

(57) ABSTRACT

Provided is a simulation apparatus. The simulation apparatus may include an evacuation unit configured to simulate evacuation routes for occupants who are in a building when the building is on fire.

### CROSS REFERENCE TO RELATED APPLICATION

The present application claims priority to Korean Patent Application No. 10-2021-0128542, filed Sep. 29, 2021, the entire contents of which is incorporated herein for all purposes by this reference.

### BACKGROUND

### 1. Technical Field

The present disclosure relates to an apparatus and a method of simulating fire spread, or simulating evacuation of occupants from fires.

### 2. Description of the Related Art

In conventional commonly-used simulators, such as “Pathfinder” and “buildingEXODUS”, the supported exit selection models for occupants are very limited.

For example, for exit selection models, only three categories are supported: the shortest distance, the shortest time, and user designation.

These limited exit selection models cannot incorporate the occupant's detour behavior to find an alternative exit if flames or smoke are encountered on the way to a nearby exit.

### SUMMARY

The present disclosure is directed to providing a simulation apparatus and method for achieving escape from a building on fire by using a detour in a situation in which it is difficult to access an exit at the shortest distance because of a fire.

The simulation apparatus of the present disclosure may include an evacuation unit configured to simulate evacuation routes of occupants who are in a building when the building is on fire.

When a limiting factor is defined, including at least one of flame, smoke, or obstacle due to a fire, the evacuation unit is configured to generate a detour path that bypasses the limiting factor for the particular occupant if the limiting factor is present between the particular occupant and the shortest distance outlet.

The simulation method of the present disclosure comprises: a reception step of receiving building information, placement information of occupants who are present in the building, and fire information including the limiting factors; a determination step of determining at least one of the occupants as a recognizing occupant who is present in a recognition area in which the limiting factor is visually recognized by using the building information, the placement information, and the fire information; a calculation step of calculating distances from a current location of the recognizing occupant to a plurality of exits for escaping from the building, and calculating a degree of risk in the limiting factor present on a moving route from the current location to each of the exits; and a selection step of selecting a detour from a plurality of the moving routes by using the distances and the degrees of risk.

According to the present disclosure, not only the fire and the evacuation simulation are superimposed and visualized, but also realistic evacuation simulation in which occupants select routes dynamically in response to a fire is achieved.

According to the present disclosure, evacuation simulation in which the behavior pattern of occupants selecting detours spontaneously in a fire situation is applied is achieved.

In the related art, fire simulation and escape simulation have not been integrated, so a building is tested for escape safety through separate execution of the two types of simulation. Although there is a system that partially integrates the two types of simulation, unrealistic escape behavior and evacuation behavior are described because the selection of a detour is not considered.

According to the present disclosure, the evacuation form of occupants is realistically described, so an escape safety test result with high reliability can be derived.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic diagram illustrating a simulation apparatus according to the present disclosure;

FIG. 2 is a block diagram illustrating an evacuation unit;

FIG. 3 is a schematic diagram illustrating a floor field model (FFM);

FIG. 4 is a diagram illustrating a limiting factor area;

FIG. 5 is a diagram illustrating a recognition area;

FIG. 6 is a schematic diagram illustrating an evacuation simulation result of a particular building;

FIG. 7 is a flowchart illustrating a simulation method of the present disclosure; and

FIG. 8 is a diagram illustrating a computing apparatus according to the present disclosure.

### DETAILED DESCRIPTION

Hereinbelow, exemplary embodiments of the present disclosure will be described in detail with reference to the accompanying drawings such that the present disclosure can be easily embodied by those skilled in the art to which this present disclosure belongs. However, the present disclosure may be embodied in various different forms and should not be limited to the embodiments set forth herein. Further, in order to clearly explain the present disclosure, portions that are not related to the present disclosure are omitted in the drawings, and like reference numerals designate like elements throughout the specification.

In the present specification, a redundant description of the same element will be omitted.

In addition, in the present specification, it will be understood that when an element is referred to as being “coupled” or “connected” to another element, it can be directly coupled or connected to the other element or intervening elements may be present therebetween. In contrast, in the present specification, it will be understood that when an element is referred to as being “directly coupled” or “directly connected” to another element, there are no intervening elements present.

In addition, the terms used in the present specification are merely used to describe particular embodiments, and are not intended to limit the present disclosure.

In addition, in the present specification, the singular forms “a”, “an”, and “the” are intended to include the plural forms as well, unless the context clearly indicates otherwise.

In addition, it will be understood that terms such as “including”, “having”, etc. are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

In addition, in the present specification, the term “and/or” includes a combination of a plurality of items or any one of a plurality of terms. In the present specification, the expression “A or B” may include “A”, “B”, or “both A and B”.

In addition, in the present specification, well-known functions and constructions that may obscure the gist of the present disclosure will not be described.

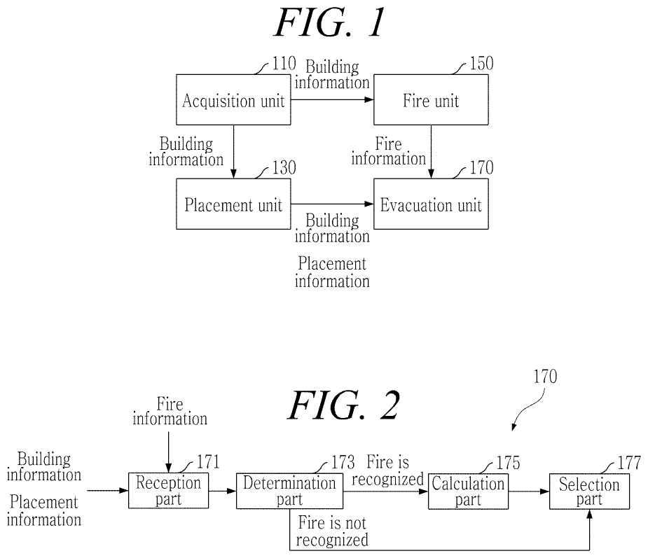

FIG. 1 is a schematic diagram illustrating a simulation apparatus according to the present disclosure.

To test a structure or building for evacuation safety (performance-oriented design), an evacuation simulator and a fire simulator may be used.

The evacuation simulator may calculate the movement of individual occupants in a 3D indoor space of a building to analyze micro-level evacuation behavior (bottlenecks, etc.) and to predict the time required for evacuation. Examples of the evacuation simulator include Pathfinder, Simulex, etc.

The fire simulator may calculate the spread of heat and smoke caused by a fire. The fire dynamics simulator (FDS) may be the fire simulator.

There is still a limitation in integrating the evacuation simulator and the fire simulator, so a test for realistic evacuation safety has difficulties. Therefore, evacuation simulation and fire simulation are performed separately, or a method of superimposing only visualizations is applied.

The evacuation simulator may be used to calculate the evacuation time, required safe egress time (RSET), taken for occupants to evacuate.

The fire simulator may be used to calculate the safe time, available safe egress time (ASET), during which a fire does not cause physical damage to occupants.

Herein, when the safe time ASET is longer than the evacuation time RSET, it may be determined that fire evacuation is safe because all occupants are able to complete evacuation before a fire spreads widely.

Some technologies for providing integrated simulation of evacuation simulation and fire simulation are commercially used (buildingEXODUS).

Occupants who have inhaled smoke lose their physical ability, and may evacuate, crawling across the floor in a space full of smoke. The existing commercial simulators may simulate moving abilities of the occupants who have inhaled smoke. However, the existing commercial simulators provide very limited evacuation route (exit) selection methods such as the shortest distance, the shortest time, and user designation (an exit specified by a user). According to the existing commercial simulators, there is a problem of not applying a dynamic evacuation route selection model that enables an occupant recognizing a limiting factor, such as heat, smoke, etc., spreading in an indoor space to move to a safe exit even with a long detour.

There is a problem of not applying the behavior pattern of occupants recognizing a fire and detouring to safe routes. The behavior pattern of the occupants detouring to safe routes may be an important factor in determining the evacuation time RSET.

Therefore, it is preferable to simulate the pattern of occupants moving along safe detours.

The present disclosure provides a simulation apparatus and method, which correspond to a fire evacuation integrated-simulation system, in which occupants' recognition of a fire and dynamic route selections corresponding thereto are considered.

In order to apply a dynamic evacuation route selection model, a simulation apparatus shown in FIG. 1 may include an acquisition unit 110, a placement unit 130, a fire unit 150, and an evacuation unit 170.

The acquisition unit 110 may acquire building information. The building information may include 2D spatial data or 3D spatial data, such as drawing files, IndoorGML, etc. The building information may include a structure of a building, a material of a building, etc.

The acquisition unit 110 may acquire the building information, such as design drawings (drawing files and CAD files) of a building, from a building server in which the building information is stored. To this end, the acquisition unit 110 may include a communication module for wired/wireless communication with the building server. Alternatively, the acquisition unit 110 may acquire the building information through a user's data input. To this end, the acquisition unit 110 may include an input means, such as a keyboard, a mouse, a touch pad, etc., operated by a user. The building information acquired by the acquisition unit 110 may be provided to the placement unit 130 and the fire unit 150.

The placement unit 130 may virtually place occupants who are people in a building indicated by the building information acquired through the acquisition unit 110. A user of the simulation apparatus may place the occupants. The placement unit 130 may include an input means for placing the occupants. The placement unit 130 may provide the evacuation unit 170 with placement information that includes locations at which occupants are placed. To generate the placement information, the placement unit 130 may be in a state in which the building information is acquired from the acquisition unit 110. The building information may be information that the evacuation unit 170 also requires. When transmitting the placement information to the evacuation unit 170, the placement unit 130 may also transmit the building information previously acquired to the evacuation unit 170.

The fire unit 150 may simulate a fire occurring in a building. The fire unit 150 may simulate an ignition location, heat release rate, smoke, spread of flame, etc. For example, the fire unit 150 may include the fire simulator, such as the fire dynamics simulator (FDS).

The evacuation unit 170 may simulate evacuation routes for occupants who are in a building when the building is on fire. For example, a floor field model (FFM) may be used as the basic model of evacuation simulation. Fire spread data calculated by the fire unit 150, such as the fire dynamics simulator (FDS), may be applied to the floor field model (FFM). An extended floor field model (FFM) considering both the spread of a fire and a dynamic route selection model may be applied to the simulation apparatus of the present disclosure.

A limiting factor including at least one selected from the group of flame, smoke, and an obstacle caused by a fire may be defined. Examples of the obstacle may include various building materials that have collapsed due to a fire, in-building furnishing articles that have fallen down on the passages due to a fire, various office supplies, etc.

In a real situation, if the limiting factor is present in a passage on the way, a person may try to escape not to an initially targeted exit but to another safe exit despite a long distance. In order to imitate such a situation as it is, when the limiting factor is present between a particular occupant and an exit at the shortest distance, the evacuation unit 170 may generate a detour for the particular occupant to bypass the limiting factor. Herein, while maintaining a particular exit initially set for a virtual particular occupant, a detour may be another route from the location of the particular occupant to the particular exit. An embodiment of selecting or generating another route to the same particular exit as a detour may be useful when a building has only one exit.

In the case in which a building has a plurality of exits for a virtual occupant to escape safely from the building, detours may not be other routes to a particular exit initially set, but routes to the other exits.

The fire unit 150 may generate fire information including the limiting factor that spreads in a building over time. The fire unit 150 may provide the fire information to the evacuation unit 170. The evacuation unit 170 may generate a detour by using the limiting factor included in the fire information.

The evacuation unit 170 may determine whether each occupant recognizes the limiting factor. The evacuation unit 170 may generate a detour only for a recognizing occupant, who recognizes the limiting factor.

The evacuation unit 170 may generate routes for the remaining occupants excluding a recognizing occupant, according to parameter setting values of an evacuation model. For example, the evacuation unit 170 may generate the shortest distance route for each of the remaining occupants from each one's location to the nearest exit.

The evacuation unit 170 may simulate an evacuation behavior along a detour according to an occupant, or may simulate an evacuation behavior according to a shortest distance route.

FIG. 2 is a block diagram illustrating the evacuation unit 170.

To generate a detour, the evacuation unit 170 may include a reception part 171, a determination part 173, a calculation part 175, and a selection part 177.

The reception part 171 may receive the building information, the placement information of occupants, and the fire information including the limiting factor. The placement information of occupants may be virtually generated, or may include locations of real occupants in a building detected by a human detection sensor. Examples of the human detection sensor may include various sensors for counting people, for example, a sensor capable of wireless communication, such as Wi-Fi, Bluetooth, etc., an infrared sensor, and a quick response (QR) code reader.

The determination part 173 may use the building information, the placement information, and the fire information to determine, as a recognizing occupant, an occupant who is present in a recognition area where the limiting factor is visually recognized.

The evacuation unit 170 may generate a detour only for a recognizing occupant so as to reduce a processing load. A real person who is unaware of the limiting factor tries to escape through the nearest exit that he or she knows. Using this fact, even though the evacuation unit generates a detour only for a recognizing occupant, there is little deterioration in the quality of a simulation result.

To the occupants who are unaware of the limiting factor caused by a fire, routes calculated in terms of probability according to parameters of the evacuation model input by a user may be given. The limiting factor may not be applied to the routes. For example, the routes may be the shortest distance routes to the nearest exits (the most common case), and routes for following nearby occupants (in the case in which a parameter of the degree of dependence on the nearby occupants is higher than a parameter of the degree of space familiarity).

The determination part 173 may repeat the process of determination of a recognizing occupant every set period.

When a particular occupant moving on the shortest route to a particular exit in the previous period enters the recognition area present on the shortest route, the determination part 173 may determine the particular occupant newly entering the recognition area as a recognizing occupant.

Instead of the existing shortest route for the particular occupant newly determined as a recognizing occupant, the evacuation unit 170 may provide the particular occupant with a detour. According to this embodiment, the shortest distance route is first applied for the same occupant, and during the occupant's escape, a detour may be newly applied instead of the shortest distance route.

The calculation part 175 may calculate distances from the current location of an occupant to a plurality of exits for escaping from the building. For example, when a building has 10 exits, a total of 10 distances from a single occupant may be calculated.

The calculation part 175 may calculate the degree of risk in the limiting factor present on the moving route from an occupant's current location to each exit.

The selection part 177 may use the distances and the degrees of risk calculated by the calculation part 175 to select a detour from the plurality of moving routes.

The calculation part 175 may calculate, for each exit, a weight function in which the distance and the degree of risk for each exit are used as factors.

The selection part 177 may select, as a detour, the moving route to a particular exit having the lowest output value of the weight function.

The processing load of the calculation part 175 may be enormous. Therefore, a method for reducing the processing load of the calculation part 175 without deterioration in probability may be provided. For example, the calculation part 175 may calculate the distance and the degree of risk only for a recognizing occupant every set period.

The selection part 177 may select a detour only for a recognizing occupant from the plurality of moving routes. The selection of a detour may correspond to the generation of a detour described above.

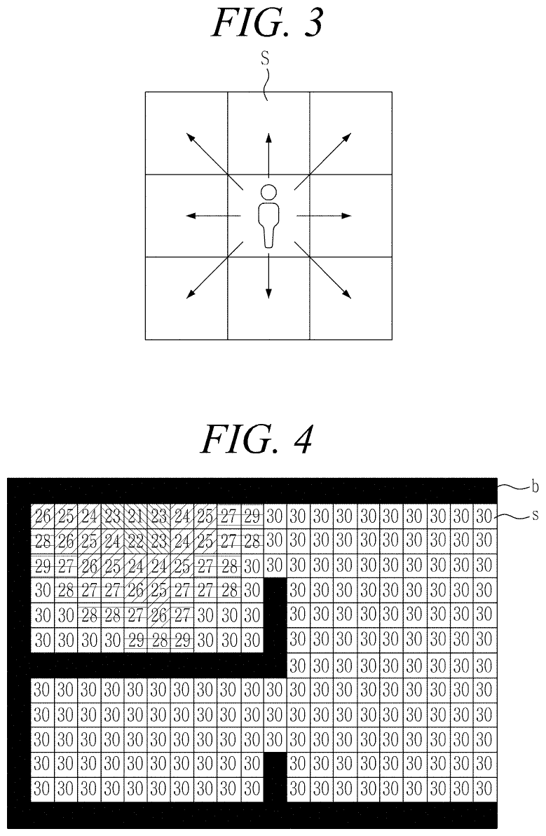

FIG. 3 is a schematic diagram illustrating a floor field model (FFM).

For example, the evacuation model, such as an extended floor field model (FFM), considering the spread of a fire and a dynamic route selection model may be newly applied to the evacuation unit 170.

According to the FFM, the evacuation unit 170 may express a target building in a 2D grid space, and may place one virtual occupant on one square s of the grid.

The size of a square s in the grid may be set considering an occupant's body size, pace, etc. The movement of an occupant is calculated in the 2D grid space, but visualization may be realized in 3D.

Considering probability values of eight nearby squares each moment (time interval) for an occupant located at the grid coordinates x and y, the evacuation unit 170 may select the square for the occupant to go.

The probability of moving to any one of the eight nearby squares may be determined considering the following factors a, b, c, d, and e (meaning data that each square has).

a. Obstacles (furniture, walls, etc.), and other occupants

b. Traces of other occupants (to consider the characteristic that an occupant follows nearby occupants when it is difficult to make a rational decision)

c. The visible distance m from the current occupant location (x, y) (to consider the characteristic (disorientation) that spatial perception is difficult when visibility is reduced because of smoke)

d. Whether a fire is recognized (to consider the situation where an occupant unaware of a fire moves to the nearest exit empirically accustomed or simply)

e. The distance to the safest exit with a fire weighting considered, or the distance to the nearest exit

In the related art, the movement probability is calculated simply using the distance to the nearest exit.

Movement probability (calculated as a normalized value)=(the degree of dependence on nearby occupants×the traces of nearby occupants)+(the degree of space familiarity×the reciprocal of the distance to the nearest exit)

The degree of dependence on nearby occupants, the traces of nearby occupants, the degree of space familiarity, and the distance to the nearest exit may correspond to the parameters of the evacuation model.

The greater the parameter of the degree of space familiarity, the better the understanding of the shortest distance, thus causing the tendency to evacuate quickly.

The higher the degree of dependence on nearby occupants is than the degree of space familiarity, the stronger the tendency to move in groups (children).

The evacuation unit 170 may calculate the movement probability for each of the eight squares near a particular occupant. The evacuation unit 170 may move the occupant to the square having the highest movement probability. According to the present disclosure, an exit may be changed according to a detour. Therefore, the processing related to a change of an exit may be additionally performed.

The evacuation unit 170 may change an exit or may generate or select a detour by using the fire weighting related to the limiting factor that varies by time point as a fire spreads.

To calculate the distance to the safest exit, the evacuation unit 170 may apply the distances from the current location of an occupant to all exits, and how much the occupant is exposed to risk in a fire while moving to each exit (the time during which the occupant is exposed to risk, the amount of toxic gasses to be inhaled (the concentration of smoke), the temperature of heat that the occupant meets while moving, and an average visible distance).

The distance to the safest exit (of the building having n exits)=Min{weight function(the distance to Exit 1, the level of risk faced when moving to Exit 1), weight function(the distance to Exit 2, the level of risk faced when moving to Exit 2), . . . , weight function(the distance to Exit n, the level of risk faced when moving to Exit n)}

The selection part 177 may use the above equation to select a particular weight function having the smaller value among the plurality of weight functions. Alternatively, the selection part 177 may select, as a detour, the route from the current location to the exit targeted by the particular weight function.

The fire weighting corresponding to the level of risk faced when moving to each exit is based on the limiting factor, and may vary by time point. Data for calculating the fire weighting may be prepared in advance using the FDS.

The fire weighting is not applied to all the occupants, but only to an occupant who recognizes a fire. For an occupant who does not recognize the fire, the movement probability may be calculated based on the distance to the nearest exit.

The determination part 173 may check whether a fire is recognized, each moment (set period) for all the occupants.

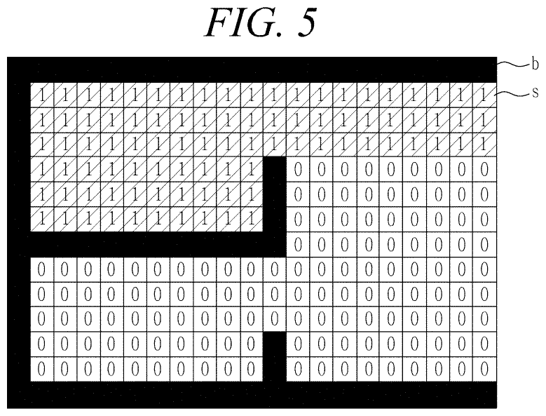

FIG. 4 is a schematic diagram illustrating a limiting factor area. FIG. 5 is a diagram illustrating a recognition area.

When an occupant is located in the recognition area (the squares having a value of “1”) shown in FIG. 5 calculated considering spread in all directions from the limiting factor area (the squares having values less than 30) shown in FIG. 4, the determination part 173 may determine the occupant as a recognizing occupant, who recognizes a fire.

FIG. 4 may show the limiting factor spread area at time point t. A value assigned to each square in the grid may be a visible distance m. A square at which the visible distance is shorter than 30 m may mean a square in which flame or smoke is present.

FIG. 5 may show the fire recognition area at time point t. When an occupant is located in any square, the square is expressed as 1 if the occupant is able to recognize a fire. Otherwise, the square is expressed as 0.

The recognition area extending from the limiting factor area may continue until meeting obstacle structures b, such as walls (black squares).

The limiting factor area changes each time point, so the recognition area may also change each time point.

The fire unit 150 may output a fire spread result for each time step on the basis of a grid resolution and time interval that a user inputs.

The fire information corresponding to the fire spread results may include the concentration of smoke, the heat (temperature), and a visible distance for each square in the grid. The fire unit 150 may calculate the fire information of the next period (time point) in advance with the same grid resolution as the evacuation model of the evacuation unit 170, and may provide the fire information to the evacuation unit 170. The evacuation unit 170 may calculate the distance to the safest exit for a recognizing occupant by matching the fire information provided from the fire unit 150 to the time point. A route to a particular exit targeting the safest exit may be a detour.

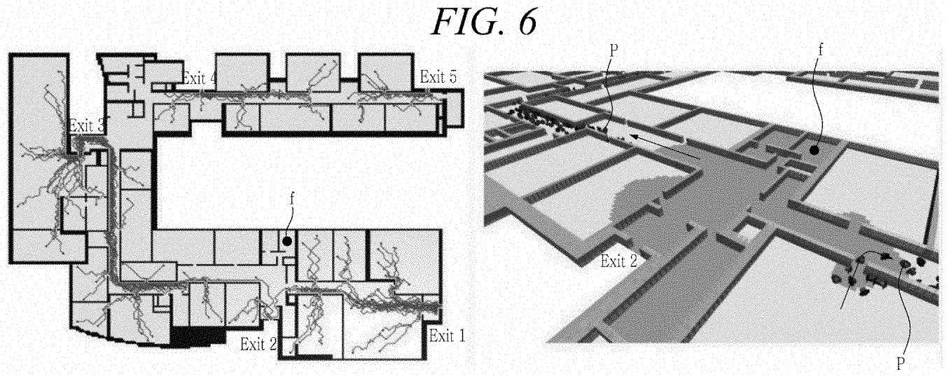

FIG. 6 is a schematic diagram illustrating an evacuation simulation result of a particular building.

The fire unit 150 may select the point near a second exit Exit 2 as an ignition point f, and the limiting factor may spread starting from the ignition point f.

When a fire alarm is sounded, virtual occupants p in the building may escape from the building through various exits by the evacuation unit 170. Herein, occupants p who are in the room near the second exit Exit 2 may move along the shortest distance route to the second exit Exit 2 nearest from the current locations. The occupants p may enter a recognition area where the limiting factor on the shortest distance route is recognized, and may be set as recognizing occupants, who recognize the limiting factor. The recognizing occupants are newly given a detour by the evacuation unit 170 to bypass the limiting factor, and may move along the detour.

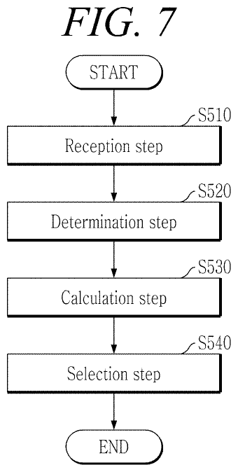

FIG. 7 is a flowchart illustrating a simulation method of the present disclosure.

The simulation method of FIG. 7 may be performed by the simulation apparatus of FIG. 1 or the evacuation unit 170 of FIG. 2.

The simulation method may include a reception step S510, a determination step S520, a calculation step S530, and a selection step S540.

In the reception step S510, the building information, the placement information of occupants who are present in the building, and the fire information including the limiting factor may be received. The reception step S510 may be performed by the reception part 171.

In the determination step S520, the building information, the placement information, and the fire information may be used to determine, as a recognizing occupant, an occupant who is present in a recognition area where the limiting factor is visually recognized. The determination step S520 may be performed by the determination part 173.

In the calculation step S530, distances from the current location of the recognizing occupant to a plurality of exits for escaping from the building may be calculated, and the degree of risk in the limiting factor present on the moving route from the current location to each of the exits may be calculated. The calculation step S530 may be performed by the calculation part 175.

In the selection step S540, the distances and the degrees of risk calculated in the calculation step S530 may be used together to select a detour from the plurality of moving routes. The selection step S540 may be performed by the selection part 177.

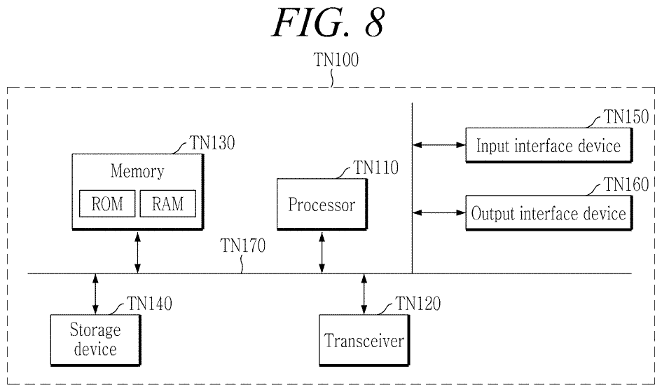

FIG. 8 is a diagram illustrating a computing apparatus according to the present disclosure. The computing apparatus TN100 of FIG. 8 may be the apparatus (for example, the simulation apparatus) described in the present specification.

In the embodiment of FIG. 8, the computing apparatus TN100 may include at least one processor TN110, a transceiver TN120, and a memory TN130. Further, the computing apparatus TN100 may include a storage device TN140, an input interface device TN150, and an output interface device TN160. The elements included in the computing apparatus TN100 may be connected to each other via a bus TN170 to communicate with each other.

The processor TN110 may execute program commands stored in either the memory TN130 or the storage device TN140 or both. The processor TN110 may mean a central processing unit (CPU), a graphics processing unit (GPU), or a dedicated processor for performing the methods according to the embodiments of the present disclosure. The processor TN110 may be configured to realize the described procedures, functions, and methods related to the embodiments of the present disclosure. The processor TN110 may control each element of the computing apparatus TN100.

Each of the memory TN130 and the storage device TN140 may store therein various types of information related to the operation of the processor TN110. Each of the memory TN130 and the storage device TN140 may be provided as either a volatile storage medium or a non-volatile storage medium or both. For example, the memory TN130 may be either a read only memory (ROM) or a random access memory (RAM) or both.

The transceiver TN120 may transmit or receive wired signals or wireless signals. The transceiver TN120 may be connected to a network to perform communication.

In the meantime, the embodiments of the present disclosure are realized not only through the above-described apparatus and/or method, but also through programs that realize functions corresponding to the construction of the embodiments of the present disclosure or through recording media having the programs recorded thereon, and this realization may be easily achieved by a person skilled in the art from the above description of the embodiments.

Although preferred embodiments of the present disclosure have been described for illustrative purposes, those skilled in the art will appreciate that various modifications, additions and substitutions are possible, without departing from the scope and spirit of the disclosure as disclosed in the accompanying claims.

What is claimed is:

1. A simulation apparatus, comprising:
an evacuation unit configured to simulate evacuation routes for occupants who are in a building when the building is on fire,
wherein under a definition of a limiting factor including at least one selected from a group of flame, smoke, and an obstacle caused by a fire, when the limiting factor is present between a particular occupant among the occupants and an exit at the shortest distance, the evacuation unit is configured to generate a detour for the particular occupant to bypass the limiting factor.

2. The simulation apparatus of claim 1, further comprising a fire unit configured to simulate the fire occurring in the building,
wherein the fire unit is configured to generate fire information including the limiting factor that spreads over time, and
the evacuation unit is configured to generate the detour by using the limiting factor included in the fire information.

3. The simulation apparatus of claim 1, wherein the evacuation unit is configured to determine whether each of the occupants recognizes the limiting factor, and to generate the detour only for a recognizing occupant who recognizes the limiting factor.

4. The simulation apparatus of claim 1, wherein the evacuation unit comprises a reception part and a determination part,
the reception part is configured to receive building information, placement information of the occupants, and fire information including the limiting factor,
the determination part is configured to use the building information, the placement information, and the fire information to determine at least one of the occupants who is present in a recognition area where the limiting factor is visually recognized, as a recognizing occupant, and
the evacuation unit is configured to generate the detour only for the recognizing occupant.

5. The simulation apparatus of claim 4, wherein the determination part is configured to repeat a process of determination of the recognizing occupant every set period,
the determination part is configured to determine, when a particular occupant moving on the shortest route to a particular exit in a previous period enters the recognition area on the shortest route, the particular occupant newly entering the recognition area as the recognizing occupant, and
the evacuation unit is configured to provide the particular occupant with the detour instead of the existing shortest route for the particular occupant newly determined as the recognizing occupant.

6. The simulation apparatus of claim 4, wherein the evacuation unit is configured to generate routes for the remaining occupants excluding the recognizing occupant, according to parameter setting values of an evacuation model.

7. The simulation apparatus of claim 1, wherein the evacuation unit comprises a calculation part and a selection part,
the calculation part is configured to calculate distances from a current location of the particular occupant to a plurality of the exits for escaping from the building,
the calculation part is configured to calculate a degree of risk in the limiting factor present on a moving route from the current location to each of the exits, and
the selection part is configured to select the detour from a plurality of the moving routes by using the distances and the degrees of risk calculated by the calculation part.

8. The simulation apparatus of claim 7, wherein the calculation part is configured to calculate, for the respective exits, weight functions in which the distances and the degrees of risk for the respective exits are used as factors, and
the selection part is configured to select, as the detour, the moving route to a particular one of the exits that has the lowest output value of the weight function.

9. The simulation apparatus of claim 7, wherein the evacuation unit comprises a determination part configured to use building information, placement information of the occupants, and fire information including the limiting factor to determine at least one of the occupants who is present in a recognition area where the limiting factor is recognized, as a recognizing occupant,
the calculation part is configured to calculate the distances and the degrees of risk only for the recognizing occupant every set period, and
the selection part is configured to select the detour from the plurality of the moving routes only for the recognizing occupant.

10. A simulation method performed by a simulation apparatus, the method comprising:
under a definition of a limiting factor including at least one selected from a group of flame, smoke, and an obstacle caused by a fire in a building,
receiving, in a reception step, building information, placement information of occupants who are present in the building, and fire information including the limiting factor;
determining, in a determination step, at least one of the occupants who is present in a recognition area where the limiting factor is visually recognized, as a recognizing occupant by using the building information, the placement information, and the fire information;
calculating, in a calculation step, distances from a current location of the recognizing occupant to a plurality of exits for escaping from the building, and calculating a degree of risk in the limiting factor present on a moving route from the current location to each of the exits; and
selecting, in a selection step, a detour from a plurality of the moving routes by using the distances and the degrees of risk.
